(19) United States
(12) Patent Application Publication
(10) Pub. No.: US 2020/0223027 A1
(43) Pub. Date: Jul. 16, 2020

(54) SUBSTRATE PROCESSING APPARATUS, AND METHOD FOR SPECIFYING AREA TO BE PARTIALLY POLISHED BY SUBSTRATE PROCESSING APPARATUS

(71) Applicant: Ebara Corporation, Tokyo (JP)

(72) Inventors: Katsuhide WATANABE, Tokyo (JP); Itsuki KOBATA, Tokyo (JP)

(73) Assignee: Ebara Corporation, Tokyo (JP)

(21) Appl. No.: 16/715,403

(22) Filed: Dec. 16, 2019

(30) Foreign Application Priority Data
Jan. 11, 2019 (JP) 2019-003449

(51) Int. Cl. B24B 37/005; H01L 21/67; H01L 21/02; B24B 57/02

(52) U.S. Cl. CPC B24B 37/005; H01L 21/67253; B24B 57/02; H01L 21/02057; H01L 21/02013

(57) ABSTRACT

To quickly grasp a film thickness distribution of a film to be processed on a substrate after CMP and realize high-speed substrate processing, an embodiment of the present invention provides a method for specifying an area to be partially polished by a partial polishing device in a substrate processing apparatus. The substrate processing apparatus includes a substrate polishing device that polishes an entire surface of a film to be processed formed on at least one surface of the substrate. The substrate polishing device includes a film thickness sensor. The substrate processing apparatus further includes the partial polishing device that further partially polishes the film to be processed of the substrate polished by the substrate polishing device. The method includes specifying an area to be partially polished by the partial polishing device based on film thickness distribution data of the film to be processed obtained from the film thickness sensor of the substrate polishing device.

### CROSS-REFERENCE TO RELATED APPLICATION

This application is based upon and claims the benefit of priority of the prior Japanese Patent Application No. 2019-3449, filed on Jan. 11, 2019, the entire content of which is incorporated herein by reference.

### TECHNICAL FIELD

The present invention relates to a substrate processing apparatus including a substrate polishing device for polishing the entire surface of a film to be processed formed on at least one surface of a substrate by chemical mechanical polishing (CMP) and a partial polishing device for further partially polishing the film to be processed of the substrate polished by the substrate polishing device and relates to a method for specifying an area to be partially polished in the substrate processing apparatus.

### BACKGROUND

In recent years, a processing apparatus has been used to perform various types of processing on a processing object (e.g., a substrate such as a semiconductor substrate or various films formed on a surface of the substrate). An apparatus including a CMP device that performs processing for polishing a processing object is an exemplary processing apparatus.

The substrate processing apparatus includes a polishing unit configured to perform processing for polishing a processing object, a cleaning unit configured to perform processing for cleaning and drying the processing object, and a load/unload unit configured to transfer the processing object to the polishing unit and receive the processing object cleaned and dried by the cleaning unit. Further, the substrate processing apparatus includes a conveyance mechanism for conveying the processing object in the polishing unit, the cleaning unit, and the load/unload unit. While the processing object is conveyed by the conveyance mechanism, the substrate processing apparatus sequentially performs various types of processing including polishing, cleaning, and drying.

The accuracy required for each process in the manufacturing of recent semiconductor devices has already reached the order of several nanometers, and the CMP is no exception. In order to satisfy this requirement, optimization of polishing and cleaning conditions is performed in the CMP. However, even if optimum conditions are determined, it is inevitable that polishing and cleaning performances possibly change due to variations in controlling constituent components or aging variation of consumables. In addition, the semiconductor wafer itself to be processed has variations. For example, there are variations in the film thickness of a film or the shape of a device formed on the processing object before CMP. These variations become apparent during and after CMP, as variations in remaining films, incompleteness in level difference elimination, or as a film residue in the polishing of a film to be completely removed. Such variations occur within a wafer surface in the form of between chips or across chips, and occur between wafers or between lots. At present, to cope with this problem, polishing conditions (e.g., a pressure distribution applied to the wafer surface during polishing, the number of rotations of a wafer holding table, and slurry) and cleaning conditions are controlled for a wafer during or before polishing, and/or a rework (re-polishing) is performed on a wafer if the variation exceeds a threshold, thereby suppressing the variation within a certain threshold.

However, since the effects of suppressing variations due to the above-described polishing conditions appear mainly in the radial direction of the wafer, it is difficult to adjust variations in the circumferential direction of the wafer. Further, the local polishing amount distribution in the wafer surface may vary depending on processing conditions during CMP and the state of a lower layer of the film polished by CMP. In addition, regarding the control of the polishing distribution in the radial direction of the wafer during CMP, since the device area in the wafer surface has been expanded from the viewpoint of recent yield improvement, it is necessary to adjust the polishing distribution in a region extending to the edge of the wafer. In the edge region of the wafer, the influence of variations in polishing pressure distribution and inflow of slurry as a polishing material becomes larger, compared to the central region of the wafer. The polishing unit configured to perform CMP basically controls the polishing conditions and cleaning conditions and performs the rework. In this case, a polishing pad is mostly in contact with the wafer surface at the entire surface thereof. Even when the contact of the polishing pad is partly, the contact area between the polishing pad and the wafer must be large enough from the viewpoint of maintaining the processing speed. In such a situation, for example, if it is required to perform a rework or the like in a specific area on the wafer surface to correct a variation exceeding the threshold, the largeness of the contact area will necessitate performing polishing even in a region where no rework is required. As a result, it becomes difficult to perform correction within the originally required threshold range. Therefore, it is required to provide a method and an apparatus that can control polishing and cleaning states in a smaller area and can perform reprocessing such as control of processing conditions and rework at an arbitrary position in the wafer surface.

In order to satisfy this requirement, there is a conventionally known partial polishing device that polishes (corrects, or reworks (reprocesses)) a part of a substrate after CMP polishing applied to the substrate entirely (PTL 1).

### CITATION LIST

### Patent Literature

PTL 1: Japanese Patent Application Laid-Open No. 2018-134710

### SUMMARY

In order to specify a location or an area to be partially polished by the partial polishing device, it is necessary to detect the state of a processing object before partial polishing (after CMP), for example, film thickness distribution of a film to be processed on a substrate. Further, it is necessary to specify the location or area to be partially polished based on differences between the detected film thickness distribution and a target film thickness distribution. For example, the partial polishing device disclosed in PTL 1 is provided with a state detection unit (reference numeral 420). The state detection unit disclosed in PTL 1 detects the film thickness distribution of a film to be processed formed on a substrate. Upon receiving a signal from the state detection unit, a control unit calculates polishing positions to be polished by the partial polishing device and a target polishing amount at each polishing position.

In PTL 1, it will be necessary to provide a step of detecting the film thickness distribution of the film to be processed on the substrate, after CMP polishing of the entire surface of the film to be processed on the substrate, and before partial polishing of the film to be processed on the substrate after CMP. Here, in the step of detecting the film thickness distribution of the film to be processed, the measurement is performed by a conventional measurement means of eddy current type, optical type, or the like depending on the film quality of the film to be processed. In the case of measuring the film thickness distribution of the film to be processed in the substrate surface by the above-mentioned measurement means, it may take a relatively long time. Particularly, when correcting the film thickness by highly accurate partial polishing, the number of measurement points becomes enormous and accordingly this step requires a lot of time. In such a situation, in PTL 1, it takes a long time to execute partial polishing on the substrate, and as a result, the speed of processing the substrate will be significantly reduced.

In view of the above-mentioned problem, the present application intends to quickly grasp the film thickness distribution of a film to be processed on a substrate after CMP and to realize high substrate processing speed.

The present application discloses, as an embodiment, a method for specifying an area to be partially polished by a partial polishing device in a substrate processing apparatus. The substrate processing apparatus includes a substrate polishing device that polishes an entire surface of a film to be processed formed on at least one surface of a substrate and includes a film thickness sensor, and the partial polishing device that further partially polishes the film to be processed of the substrate polished by the substrate polishing device. The method includes specifying an area to be partially polished by the partial polishing device based on film thickness distribution data of the film to be processed obtained from the film thickness sensor of the substrate polishing device.

### BRIEF DESCRIPTION OF DRAWINGS

FIG. 1 is a top view of a substrate processing apparatus;

FIG. 2 is a front view of a substrate polishing device;

FIG. 3 is a diagram illustrating the trajectory of a film thickness sensor viewed from a substrate;

FIG. 4 is a graph schematically illustrating profiles of signals output from the film thickness sensor;

FIG. 5 is a schematic diagram of a sensor output map;

FIG. 6 is a perspective view of a partial polishing device;

FIG. 7 is a schematic diagram illustrating a plurality of polishing heads;

FIG. 8 is a flowchart illustrating an exemplary method for polishing a substrate by the substrate processing apparatus;

FIG. 9 is a graph illustrating exemplary processing by a control unit; and

FIG. 10 is a graph illustrating exemplary processing by the control unit.

### DESCRIPTION OF EMBODIMENTS

<Overview of Substrate Processing Apparatus>

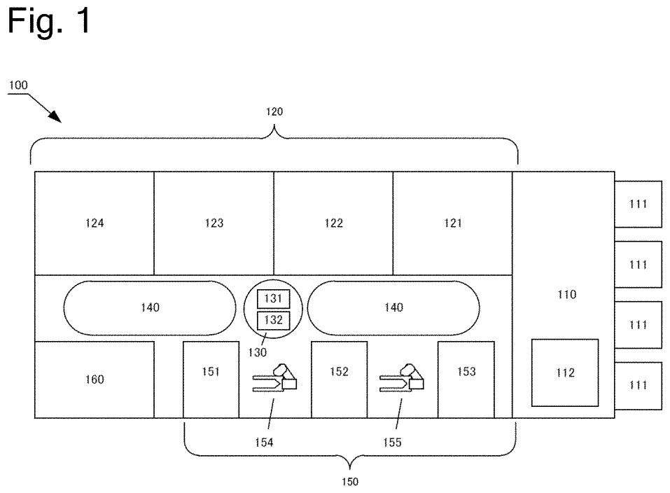

FIG. 1 illustrates a top view of a substrate processing apparatus 100 according to an embodiment. Note that FIG. 1 and other drawings are schematic. For example, an actual substrate processing apparatus may have a shape different from the example in FIG. 1. For example, the actual substrate processing apparatus may have constituent components not illustrated in FIG. 1. Specific configurations of the substrate processing apparatus and components thereof are not limited to configurations described below.

The substrate processing apparatus 100 illustrated in FIG. 1 includes a load/unload unit 110 and a polishing unit 120. The substrate processing apparatus 100 further includes substrate conveying units 130 and 140, a substrate cleaning and drying unit 150, and a control unit 160. The load/unload unit 110 may include FOUPs 111 and a conveyance robot 112 of the load/unload unit. The polishing unit 120 may include a first polishing device 121, a second polishing device 122, a third polishing device 123, and a fourth polishing device 124. At least one of the first polishing device 121 to the fourth polishing device 124 may be a general CMP device that polishes the entire surface of at least one surface of a substrate. The CMP device includes a polishing table (not illustrated) on which a polishing pad is attached, and a top ring (not illustrated) to which a substrate is attached. At least one of the first polishing device 121 to the fourth polishing device 124 includes a partial polishing device. The partial polishing device may be provided additionally or alternatively, independently of the substrate processing apparatus 100. The first polishing device 121 to the fourth polishing device 124 may have both a CMP function and a partial polishing function. The partial polishing device will be described in detail below. Further, regarding the substrate conveying units 130 and 140, for example, the substrate conveying unit 140 is a linear transporter. The linear transporter may have a function of transferring a substrate to each polishing device of the polishing unit 120. Further, the substrate conveying unit 130 may include a conveyance robot 131 that transfers a substrate between linear transporters 140 and a station 132 that temporarily places a substrate before the substrate is transferred to a first cleaning unit conveyance robot 154 described below. Further, as illustrated in the drawing, the substrate cleaning and drying unit 150 may include a first cleaning module 151, a second cleaning module 152, and a drying module 153. The substrate cleaning and drying unit 150 may further include the first cleaning unit conveyance robot 154 and a second cleaning unit conveyance robot 155.

The load/unload unit 110 is provided for loading a substrate that needs to be processed from the outside of the substrate processing apparatus 100, and for unloading the processed substrate from the inside of the substrate processing apparatus 100. The FOUP 111 can accommodate a substrate or a substrate cassette in which a substrate is accommodated. The conveyance robot 112 of the load/unload unit receives/transfers a substrate from/to a desired FOUP 111. The substrate received by the conveyance robot 112 of the load/unload unit may be sent to the polishing unit 120 by the substrate conveyance unit 140 described below and/or any other mechanism (not illustrated).

The substrate polished by the polishing unit 120 is conveyed to the station 132 of the substrate conveying unit 130 using the substrate conveyance unit 140 and the conveyance robot 131 in the substrate conveying unit 130. The station 132 is configured to hold a polished substrate before it is cleaned. The station 132 may be configured to hold a plurality of substrates. The substrate conveyance unit 140 and the conveyance robot 131 are configured to convey a substrate from the polishing unit 120 to the station 132 of the substrate conveying unit 130. As described above, the substrate conveyance unit 140 may carry out at least a part of the conveyance of a substrate between the load/unload unit 110 and the polishing unit 120.

The substrate held on the station 132 is conveyed to the substrate cleaning and drying unit 150. The conveyance of the substrate between the station 132 and the substrate cleaning and drying unit 150 is performed by the first cleaning unit conveyance robot 154. The substrate conveyed to the substrate cleaning and drying unit 150 is cleaned by each cleaning module (i.e., the first cleaning module 151 and the second cleaning module 152). Here, for the cleaning of the substrate, it may be desired to appropriately combine contact cleaning and non-contact cleaning. An example of the contact cleaning is, for example, roll cleaning in which a roll-shaped PVA sponge is brought into contact with front and back surfaces of a substrate and the substrate and the PVA sponge are caused to relatively move in chemical liquid or pure water supplied. Another example is cleaning in which the substrate is swung in a state where a pencil-shaped small-diameter PVA sponge is brought into contact with the substrate. An example of the non-contact cleaning is, for example, megasonic cleaning or high-pressure jet cleaning. In the drying module 153, the substrate cleaned by the cleaning module is dried. Here, as an exemplary drying method, it is possible to appropriately select a method for removing the liquid adhering to the substrate by rotating the substrate at a high speed or a method for rotating the substrate at a high speed while supplying an IPA containing gas. The drying module 153 may have a function of carrying out a final cleaning process as a cleaning module in addition to the function of drying the substrate. Although the two-stage cleaning module is illustrated in the drawing, a third cleaning module may be provided additionally or alternatively in front of the drying module 153.

The first cleaning unit conveyance robot 154 receives a polished substrate from the station 132 and conveys the received substrate to the first cleaning module 151. Further, the first cleaning unit conveyance robot 154 receives the substrate cleaned by the first cleaning module 151 and conveys the received substrate to the second cleaning module 152. The second cleaning unit conveyance robot 155 receives the substrate cleaned by the second cleaning module 152 and conveys the received substrate to the drying module 153. The substrate dried by the drying module 153 is taken out from the drying module 153 by an appropriate means, for example, the conveyance robot 112, the substrate conveyance unit 140 or any other conveyance device (not illustrated). The substrate taken out from the drying module 153 is carried into the load/unload unit 110. The load/unload unit 110 finally unloads the substrate from the substrate processing apparatus 100.

<Details of Substrate Polishing Device>

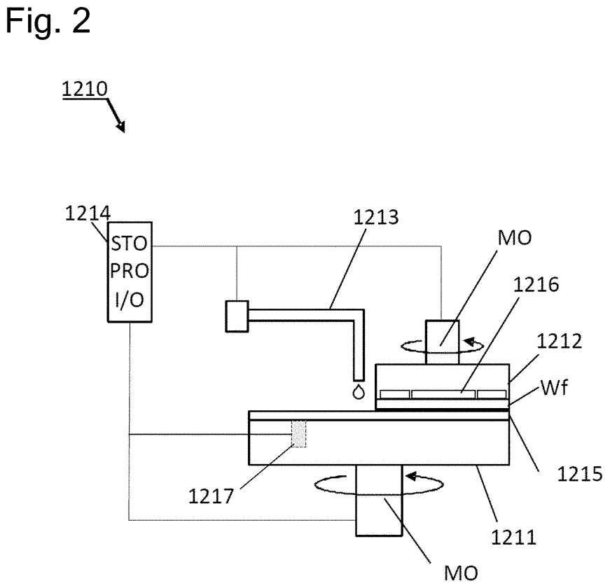

FIG. 2 is a front view of a substrate polishing device 1210 according to an embodiment. The substrate polishing device 1210 illustrated in FIG. 2 may be at least a part of the polishing unit 120. For example, the substrate polishing device illustrated in FIG. 2 is the first polishing device 121.

The substrate polishing device 1210 according to an embodiment includes a polishing table 1211, a polishing head 1212, a liquid-feed mechanism 1213, and a control unit 1214. For example, the control unit 1214 may include a storage device STO, a processor PRO, and an input/output device I/O. The control unit 1214 may be identical to or different from the control unit 160 of the substrate processing apparatus 100.

A polishing pad 1215 is detachably attached to an upper surface of the polishing table 1211. Here, the “upper surface” of the polishing table 1211 is a technical term indicating a surface of the polishing table 1211 that faces the polishing head 1212. Accordingly, the “upper surface” of the polishing table 1211 is not limited to “a surface positioned in the vertically upward direction”. The polishing head 1212 is provided in such a manner that it faces the polishing table 1211. A substrate Wf is detachably attached to the surface of the polishing head 1212 that faces the polishing table 1211. The liquid-feed mechanism 1213 is configured to supply polishing liquid such as slurry to the polishing pad 1215. The liquid-feed mechanism 1213 may be configured to supply pure water, cleaning liquid, or chemical liquid, in addition to the polishing liquid.

The substrate polishing device 1210 according to an embodiment can bring the substrate Wf into contact with the polishing pad 1215 by causing a vertical movement mechanism (not illustrated) to lower the polishing head 1212, after the substrate Wf is transferred from the substrate conveyance unit to the polishing head. The vertical movement mechanism may be an air cylinder type or a position control type using a ball screw. Further, each of the polishing table 1211 and the polishing head 1212 can be rotated by a dedicated motor MO (this motor may be referred to as a “relative motion mechanism”). The substrate polishing device 1210 brings the substrate Wf into contact with the polishing pad 1215, and polishes a processing target film of the substrate Wf by rotating at least one, preferably both, of the polishing table 1211 and the polishing head 1212 in a state where the polishing liquid is supplied by the liquid-feed mechanism 1213.

Further, the substrate polishing device 1210 may have an airbag 1216 divided into a plurality of sections in the polishing head 1212. Additionally or alternatively, the airbag 1216 may be provided on the polishing table 1211. The airbag 1216 is a rubber-like member for adjusting the polishing pressure for each area of the substrate Wf. The airbag 1216 is configured in such a manner that the volume thereof is changeable depending on the pressure of fluid introduced therein. Note that any fluid other than air such as nitrogen gas or pure water may be introduced into the airbag 1216, although it is named “air” bag.

The polishing table 1211 is provided with a film thickness sensor 1217. The film thickness sensor 1217 is a sensor capable of measuring the thickness of a film formed on the substrate Wf or the thickness of the substrate itself (hereinafter, both are simply referred to as “film thickness”). The film thickness sensor 1217 is, for example, an eddy current sensor, an optical sensor, or another sensor. The eddy current sensor is mainly effective when used for a film having electrical conduction property such as a metal film, and the optical sensor is effective for a film having light transmission property. The film thickness sensor 1217 is typically installed at a position of the polishing table 1211 on a locus passing through the center of the substrate Wf during polishing. However, the film thickness sensor 1217 may be provided in another place, for example, in the vicinity of the center of the polishing table 1211 for the purpose of precisely measuring the edge of the substrate Wf. Further, two or more film thickness sensors 1217 may be provided. The time required for measuring the film thickness of a film to be processed on the substrate Wf with this film thickness sensor, per point, is on the order of pec to msec. Accordingly, when the film thickness sensor 1217 passes through the substrate Wf, it is possible to measure the film thickness distribution at a plurality of points on the locus passing through the surface of the substrate Wf.

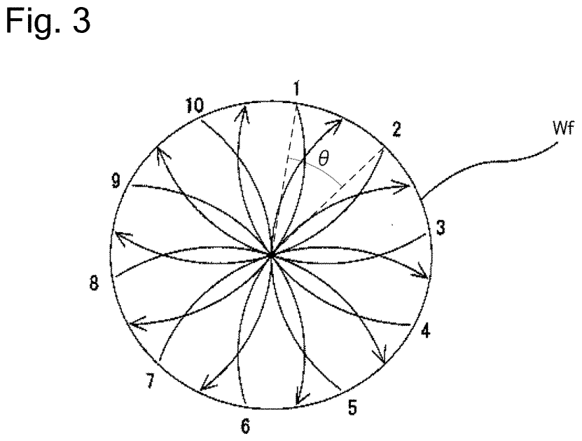

When each constituent component has no error in dimension, assembling, and rotational speed, and when the combination of rotational speed of the polishing table 1211 and rotational speed of the polishing head 1212 is a predetermined one, the trajectory of the film thickness sensor 1217 viewed from the substrate Wf is limited to several patterns. As an example, FIG. 3 illustrates the trajectory of the film thickness sensor 1217 viewed from the substrate Wf when the rotational speed of the polishing table 1211 is 70 rpm (70 min⁻¹) and the rotational speed of the polishing head 1212 is 77 rpm (77 min⁻¹). In FIG. 3, each solid line with an arrow indicates the trajectory of the film thickness sensor 1217. Under the above conditions, the trajectory of the film thickness sensor 1217 rotates 36 degrees each time the polishing table 1211 makes a complete rotation. In other words, interval θ of trajectories of the film thickness sensor 1217 viewed from the substrate Wf is 36 degrees. Accordingly, the number of trajectories in this case is 10 (=360 (degrees)/36 (degrees/piece)). Reference numerals “1” to “10” in FIG. 3 represent first-round trajectory to tenth-round trajectory of the film thickness sensor 1217.

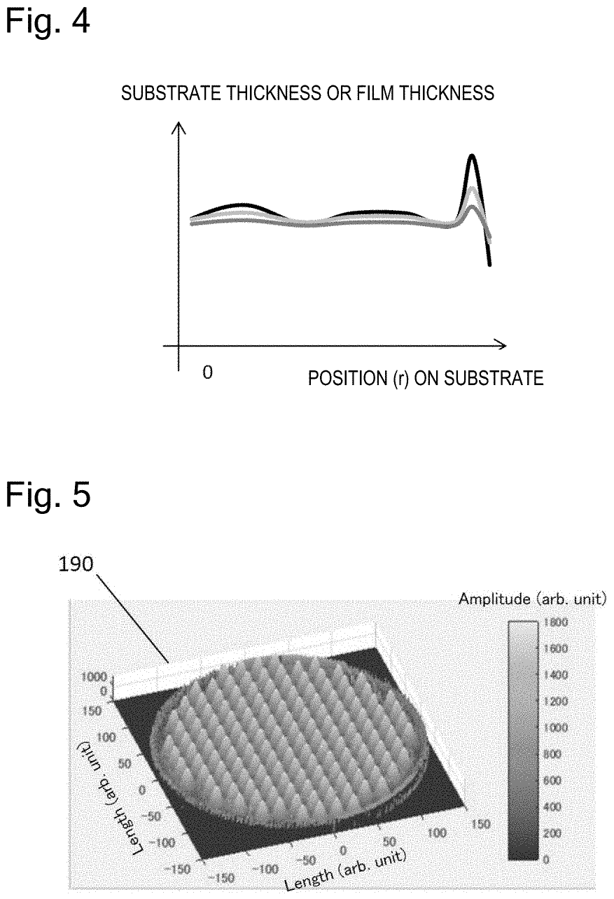

The typical film thickness sensor 1217 measures the film thickness at a plurality of points passing through the center of the substrate Wf within the surface thereof when passing through the substrate Wf. As described with reference to FIG. 3, the film thickness sensor 1217 measures the film thickness of the film to be processed on the substrate Wf while moving along the plurality of trajectories within the surface of the substrate Wf by combinations with respect to the number of rotations between the substrate Wf and the polishing table 1211. FIG. 4 illustrates exemplary profiles of the output signal of the film thickness sensor 1217 (note that the position on the substrate is determined based on the radius in FIG. 4). As one example, FIG. 4 illustrates output signals on three trajectories. Further, as described above, there may be a plurality of trajectories of the film thickness sensor 1217. Therefore, it is possible to generate a map (see FIG. 5) representing positional dependency of the film thickness from combinations of a plurality of locus of the output signal of the film thickness sensor 1217. This map, that is, a map representing the magnitude of the output signal of the film thickness sensor 1217 with respect to the entire surface to be polished on the substrate Wf, is hereinafter referred to as a “sensor output map”. As described below, generating the sensor output map is not essential.

Data points of the sensor output map are two-dimensionally positioned on the substrate Wf. Since the output signal of the film thickness sensor 1217 is recorded at each data point, the sensor output map is constituted by three-dimensional data (namely, combination of two-dimensional data representing the position and one-dimensional data representing the magnitude of the output signal). It is desired that the sensor output map has a resolution (the number of data points) that can sufficiently resolve the unevenness of output signals of the film thickness sensor 1217. For example, the number of data points of the sensor output map is preferably 100 points×100 points or more, although it depends on various conditions such as the size of the substrate Wf. More preferably, it is 1000 points×1000 points or more. The coordinate system representing the data points of the sensor output map is not limited to xy coordinate system and may be rθ or another coordinate system.

The sensor output map may be acquired, for example, by being generated from actual output signals of the film thickness sensor 1217. The sensor output map is generated based on signals output from the film thickness sensor 1217 in a state where the substrate polishing device 1210 is operating, more specifically, when the polishing table 1211 and the polishing head 1212 are rotating.

When generating the sensor output map, it is desired that the interval 0 of trajectories of the film thickness sensor 1217 viewed from the substrate Wf is an interval enough for resolving the unevenness of output signals of the film thickness sensor 1217. In one example, the rotational speeds of the polishing table 1211 and the polishing head 1212 at the time of generating the sensor output map are set in such a manner that the interval θ of trajectories of the film thickness sensor 1217 viewed from the substrate Wf is 10 degrees or less. For example, the interval θ of trajectories of the film thickness sensor 1217 viewed from the substrate Wf is exactly 2 degrees, the number of trajectories is 180 (=360 (degrees)/2 (degrees/piece)). When the film thickness sensor 1217 passes through numerous trajectories on the substrate Wf, the film thickness sensor 1217 outputs signals on the entire surface of the substrate Wf. It is possible to generate and acquire the sensor output map based on the output signals for almost the entire surface of the substrate Wf. The sensor output map may be generated during polishing of the substrate Wf. The sensor output map may be generated after the polishing of the substrate Wf is completed. In the latter case, it is desired to generate the sensor output map in a state where the substrate Wf is not substantially polished. For example, it may be performed by rotating the polishing table 1211 and the polishing head 1212, after completion of the polishing, in a state where pure water is supplied from the liquid-feed mechanism 1213 and the polishing liquid is removed. According to the above-mentioned method, a sensor output map 190 illustrated in FIG. 5 can be generated.

The value of a signal output from the film thickness sensor 1217 can be profiled on an arbitrary line drawn on the acquired sensor output map (e.g., the sensor output map 190 illustrated in FIG. 5). Here, the “line” is not limited to a straight line. Accordingly, the profile on an arbitrary trajectory can be calculated from the acquired sensor output map.

<Details of Partial Polishing Device>

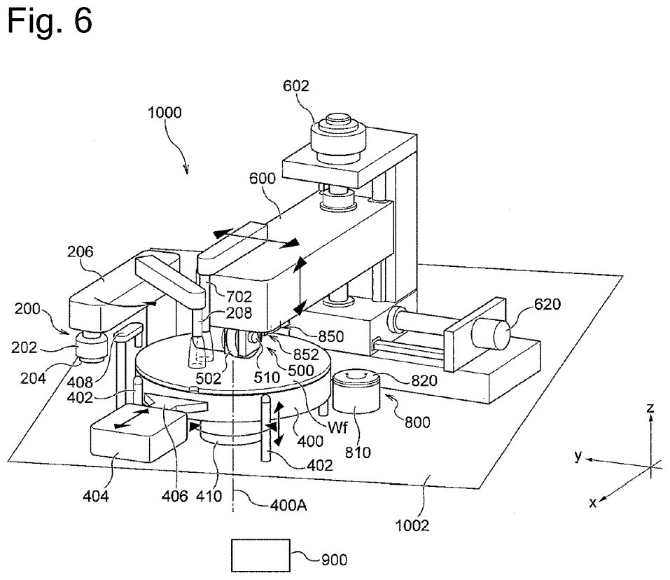

FIG. 6 is a perspective view schematically illustrating a partial polishing device 1000 according to an embodiment. The partial polishing device 1000 may be at least a part of the polishing unit 120. For example, the partial polishing device 1000 illustrated in FIG. 6 may be at least a part of at least one of the first polishing device 121 to the fourth polishing device 124. The partial polishing device 1000 according to an embodiment is disposed on a base surface 1002. The partial polishing device 1000 may be installed in a housing (not illustrated).

The partial polishing device 1000 according to an embodiment includes a stage 400 for holding the substrate Wf upwardly. The stage 400 may be able to fix the substrate Wf by arbitrary means such as vacuum suction. The partial polishing device 1000 according to an embodiment includes a plurality of lift pins 402 that can move in the vertical direction around the stage 400. The lift pins 402 may be used to receive the substrate Wf from a substrate conveyance device and place the substrate Wf on the stage 400. The partial polishing device 1000 may include a positioning mechanism 404 for positioning the substrate Wf. The positioning mechanism 404 illustrated in FIG. 6 includes a positioning pin (not illustrated) and a positioning pad 406. The positioning mechanism 404 can position the substrate Wf by pressing the positioning pad 406 against the substrate Wf in a state where the substrate Wf is placed on the lift pins 402.

The partial polishing device 1000 according to an embodiment includes a detection unit 408. The detection unit 408 detects the position of the substrate Wf disposed on the stage 400. The detection unit 408 can specify an arbitrary point of the substrate Wf with reference to the position of, for example, a notch or an orientation flat of the substrate Wf. As a result, partial polishing is feasible in a desired area.

The stage 400 is configured to be rotatable and/or angularly rotatable about a rotation axis 400A by a rotation driving mechanism 410. Here, the term “rotation” means continuous rotation in a predetermined direction, and the term “angular rotation” means motion in the circumferential direction (including reciprocating motion) in a predetermined angular range. Additionally or alternatively, the stage 400 may include a mechanism for moving the held substrate Wf horizontally.

The partial polishing device 1000 according to an embodiment includes a polishing head 500. The polishing head 500 can hold a disc-shaped polishing pad 502. Specifically, the polishing head 500 holds the polishing pad 502 in such a manner that a side surface of the polishing pad 502 faces the substrate Wf. A rotating shaft 510 is inserted in the center of the polishing pad 502. However, the shape of the polishing pad 502 is not limited to the disc shape and may be a columnar shape, a spherical shape, or the like. Further, when the polishing pad 502 is configured to move horizontally, the polishing pad 502 may have a rectangular parallelepiped shape or the like.

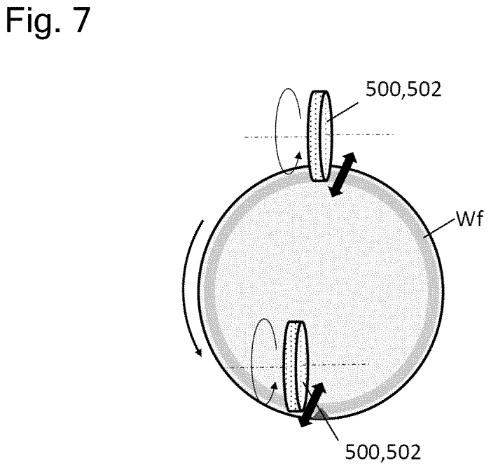

As another example, as illustrated in FIG. 7, the partial polishing device 1000 may include a plurality of polishing heads 500. When the distance between one polishing head 500 and the center of the substrate Wf is equal to the distance between the other polishing head 500 and the center of the substrate Wf, it is considered that the polishing rate of partial polishing is approximately doubled. When the distances between respective polishing heads 500 and the center of the substrate Wf are different, the plurality of polishing heads 500 can simultaneously perform partial polishing at different areas.

Here, the polishing pad 502 is formed of, for example, a foamed polyurethane hard pad, a suede soft pad, or a sponge. Here, in the control or rework for reducing variations in film thickness distribution of the film to be processed in the substrate surface, the smaller the contact area between the polishing pad 502 and the substrate Wf is, the more various variations can be coped with. Further, the type of the polishing pad may be appropriately selected depending on the material of a polishing object or the state of an area to be removed. For example, in the case where the areas to be removed are made of the same material and have local unevenness, the level difference elimination becomes important occasionally. In such a case, for the purpose of improving performances in the level difference elimination, a hard pad, namely a pad having high hardness or rigidity, may be used as the polishing pad. On the other hand, when the polishing object is a material that is low (or weak) in mechanical strength, such as a Low-k film, or when multiple materials are simultaneously processed, a soft pad may be used to reduce the damage of the surface to be polished. Further, when the polishing liquid such as slurry is used, the type of the polishing pad may be appropriately selected because the removal rate of the processing object and the occurrence of any damage cannot be determined simply by the hardness or rigidity of the polishing pad. Further, these polishing pads may have surfaces provided with groove shapes such as concentric grooves, XY grooves, spiral grooves, or radial grooves. In addition, the polishing pad may be provided with at least one hole penetrating the polishing pad itself so that the processing liquid can be supplied through the hole. Further, when the polishing pad is small and it is difficult to supply the polishing liquid through the polishing pad, a polishing liquid supply nozzle 702 may be held by, for example, a holding arm 600 so that the nozzle can move together with the holding arm 600 while the arm swings. Alternatively, the polishing liquid supply nozzle 702 may be installed independently of the holding arm 600. Further, the polishing pad may be made of a sponge-like material such as a PVA sponge, into which the processing liquid can penetrate. Thus, the flow distribution of the processing liquid on the polishing pad surface can be made uniform, and by-products removed by polishing can be quickly discharged.

The partial polishing device 1000 according to an embodiment includes the holding arm 600 for holding the polishing head 500. The holding arm 600 includes a driving mechanism for driving the polishing pad 502, such as a motor for rotating the polishing pad 502. The driving mechanism may be a mechanism capable of changing (adjusting) the rotational speed of the polishing pad 502. As another example, the driving mechanism may be a mechanism for causing the polishing pad 502 to move horizontally.

The partial polishing device 1000 according to an embodiment includes a vertical driving mechanism 602 that causes the holding arm 600 to move in a direction perpendicular to the surface of the substrate Wf (z direction in in FIG. 6). The vertical driving mechanism 602 functions as a pressing mechanism for pressing the polishing pad 502 against the substrate Wf at the time of partially polishing the substrate Wf.

The partial polishing device 1000 according to an embodiment includes a horizontal driving mechanism 620 that causes the holding arm 600 to move in a direction horizontal to the surface of the substrate Wf (x direction and/or y direction in FIG. 6).

The partial polishing device 1000 according to an embodiment includes the polishing liquid supply nozzle 702. The polishing liquid supply nozzle 702 is fluidly connected to a supply source (not illustrated) of the polishing liquid, such as slurry. In an embodiment, the polishing liquid supply nozzle 702 is held by the holding arm 600. Further, the polishing liquid supply nozzle 702 may supply pure water or cleaning chemical liquid, in addition to the polishing liquid such as slurry. Further, it is desired that the removal amount in the partial polishing is, for example, less than 50 nm, preferably 10 nm or less, in order to maintain the state (flatness and residue amount) of the polished surface after CMP. If the variation in film thickness or shape is as small as several nanometers to several tens of nanometers and the removal rate is not so high as that of ordinary CMP, the polishing rate can be adjusted by appropriately performing processing such as dilution on the polishing liquid.

The partial polishing device 1000 according to an embodiment includes a cleaning mechanism 200 for cleaning the substrate Wf. The cleaning mechanism 200 according to an embodiment includes a cleaning head 202, a cleaning member 204, a cleaning head holding arm 206, and a rinse nozzle 208. The cleaning member 204 is configured to be rotatable and contactable with the substrate Wf, and can clean the substrate Wf after partial polishing. Additionally or alternatively, a member for cleaning the substrate by a technique such as megasonic cleaning, high-pressure water cleaning, or two-fluid cleaning may be used, as the cleaning member 204. The cleaning member 204 is held by the cleaning head 202. The cleaning head 202 is held by the cleaning head holding arm 206. The cleaning head holding arm 206 includes a driving mechanism for driving, for example, rotating the cleaning head 202 and the cleaning member 204. The cleaning head holding arm 206 further includes a swing mechanism for swinging the cleaning head holding arm 206. The rinse nozzle 208 is connected to a cleaning liquid supply source (not illustrated). The cleaning liquid can be, for example, pure water or chemical liquid. The rinse nozzle 208 may also be swingable.

The partial polishing device 1000 according to an embodiment includes a conditioning unit 800 for conditioning the polishing pad 502. The conditioning unit 800 includes a dress stage 810 that holds a dresser 820. The dress stage 810 is rotatable about an axis parallel to the rotation axis 400A. When the polishing pad 502 and the dresser 820 rotate while the polishing pad 502 is pressed against the dresser 820, the polishing pad 502 is conditioned. Additionally or alternatively, the dress stage 810 may be linearly movable.

The partial polishing device 1000 according to an embodiment includes a second conditioner 850. The second conditioner 850 is a member for conditioning the polishing pad 502 that is in the process of polishing the substrate Wf. The second conditioner 850 is held by the holding arm 600 in the vicinity of the polishing pad 502. The second conditioner 850 includes a moving mechanism for moving a conditioning member 852 and pressing it against the polishing pad 502. For example, the conditioning member 852 is configured to be movable in the x direction. Further, the conditioning member 852 may be configured to be able to rotate or linearly move during conditioning by a driving mechanism (not illustrated).

The partial polishing device 1000 according to an embodiment includes a control unit 900. The control unit 900 may be identical to the control unit 160 and/or the control unit 1214 or may be an independent member.

<About Use of Output Signal of Film Thickness Sensor>

The conventional partial polishing device detects the film thickness distribution of the film to be processed on the substrate by the state detection unit provided in the partial polishing device, and specifies a location or an area to be partially polished and calculates the polishing amount based on detected data and the target film thickness distribution. This method requires a step of detecting the state before performing the partial polishing. In addition, enormous measurement time is required as described above. As a result, the lead time for the partial polishing tends to be longer. Therefore, in an embodiment, the area to be partially polished and preferably the polishing amount in this area are specified based on film thickness distribution data obtained from the film thickness sensor 1217 of the substrate polishing device 1210. According to this embodiment, since no preliminary state detection step is required, the partial polishing device 1000 can immediately start partial polishing upon receiving the substrate Wf. However, it does not mean to exclude the partial polishing device 1000 regarding the provision of the state detection unit.

Further, in general, the polishing amount tends to vary in the r direction (radial direction of the substrate Wf) rather than the θ direction (circumferential direction of the substrate Wf). Therefore, a portion of the substrate Wf insufficiently polished by the substrate polishing device 1210 tends to be formed in a ring shape. As an example, as illustrated in FIG. 4, insufficient polishing tends to occur in the vicinity of the edge of the substrate Wf (the film thickness tends to increase). Therefore, in an embodiment, a two-dimensional film thickness profile composed of the distance (r) from the center of the substrate as one dimension and the film thickness (t) as another dimension (hereinafter, referred to as “rt profile”) is used as data obtained from the film thickness sensor 1217. In this embodiment, the area to be partially polished has a ring shape. In this embodiment, using no θ-directional information can decrease the amount of information to be processed and can simply control the operation of the partial polishing device 1000. As a result, the time required for the partial polishing can be reduced. On the other hand, in this embodiment, precisely performing partial polishing on the substrate Wf is deemed to be difficult because no usage of the θ-directional information. However, as described above, since the insufficiently polished portion is typically formed in a ring shape, the disadvantage of not using the 0-directional information is small.

First, the control unit (at least one of the control unit 160, the control unit 900, and the control unit 1214: hereinafter, simply referred to as “control unit” with no reference numeral) refers to the rt profile on a certain trajectory. The rt profile includes a film thickness profile obtained from actual measurement values of the film thickness sensor 1217 (see FIG. 4) and a film thickness profile extracted from the sensor output map (see FIG. 5). In the case of using the actual measurement values of the film thickness sensor 1217, generation of the sensor output map is not essential. It is desired that the rt profile is obtained immediately before the polishing step by the substrate polishing device 1210 is completed, or after the polishing step by the substrate polishing device 1210 is completed, for example, while supplying pure water from the liquid-feed mechanism 1213, in a state where the film to be processed is not polished. Next, the control unit specifies an area to be partially polished based on differences between the film thickness profile obtained from signals output from the film thickness sensor 1217 and a target film thickness profile, and further calculates a distribution of partial polishing amounts in the area. Subsequently, the control unit controls the partial polishing device 1000 to polish the area to be partially polished. Here, although the area to be polished by partial polishing is determined by the polishing pad diameter and width, the polishing pad diameter and width are sufficiently smaller than the area to be partially polished. Therefore, in the partial polishing, polishing corresponding to the distribution of partial polishing amounts is performed by accumulating polishing at each radius of the area to be partially polished. Specifically, the horizontal driving mechanism 620 moves the polishing head 500 to the specified area to be partially polished on the substrate Wf. Subsequently, the vertical driving mechanism 602 presses the polishing pad 502 against the film to be processed on the substrate Wf. While polishing liquid is supplied from the polishing liquid supply nozzle 702, the polishing pad 502 is rotated by the driving mechanism in the holding arm 600 such as a motor for driving the polishing pad 502. While the rotation driving mechanism 410 of the stage 400 rotates the substrate Wf, the film to be processed on the substrate Wf is polished by a predetermined polishing amount in a ring shape. When the polishing amount reaches a predetermined level, the horizontal driving mechanism 620 moves the polishing head 500 to the next radial position to perform similar polishing. Here, if the moving amount of the polishing head is larger or when the area to be partially polished is discontinuously present in the radial direction, the polishing head may be moved after the rotation of the polishing pad 502 and the rotation of the substrate Wf on the stage 400 are once stopped. On the other hand, if the moving amount of the polishing head is smaller or when the area to be partially polished is continuously present in the radial direction, the polishing head may be moved while causing each of the polishing pad 502 and the substrate Wf on the stage 400 to rotate continuously. In addition, as another example, the polishing pad may be temporarily moved to the conditioning unit 800 and the polishing head may be moved to the next radial position after the conditioning of the polishing surface of the polishing pad 502 is completed.

In the above-described control, only the rt profile on one trajectory may be used. In this case, it is advantageous in that the amount of information to be processed is smaller. On the other hand, rt profiles on a plurality of trajectories may be used. In this case, it is advantageous in that the influence of errors in measurement values of the film thickness sensor 1217 or erroneous values on the profile can be reduced. In the case of using the rt profiles on a plurality of trajectories, one rt profile as a representative film thickness profile may be obtained based on the average value of film thicknesses at respective radii of the profiles. As another example, one rt profile as a representative film thickness profile may be obtained based on the average value of a profile having the maximum average film thickness and a profile having the minimum average film thickness among the plurality of rt profiles. As another example, one rt profile having a median film thickness among a plurality of profiles may be obtained as a representative film thickness profile. As one example with no intention of limitation, when film thickness distribution patterns are formed periodically in the circumferential direction on the substrate Wf, one rt profile obtained from the average value of respective profiles may be used as a representative film thickness profile. Further, as another example with no intention of limitation, when film thickness distribution patterns are formed non-periodically on the substrate Wf, one rt profile obtained based on an average value or a median value between the maximum film thickness and the minimum film thickness may be used as a representative film thickness profile.

Further, as described above, in a case where insufficient polishing occurs in the vicinity of the edge region of the substrate Wf, namely when the area to be partially polished is distributed in a specific range, only a part of the rt profile corresponding to the vicinity of the edge region may be used. Here, the vicinity of the edge region is, for example, an area corresponding to 80% to 100% of the radius of the substrate, for example, an area corresponding to 90% to 100%, for example, an area corresponding to 95% to 100%. The upper limit of the vicinity of the edge region may be set to a value lower than 100% of the radius of the substrate. For example, when the substrate has a diameter of 300 mm, the upper limit may be set to the region of 130 mm or more in the radius of the substrate Wf.

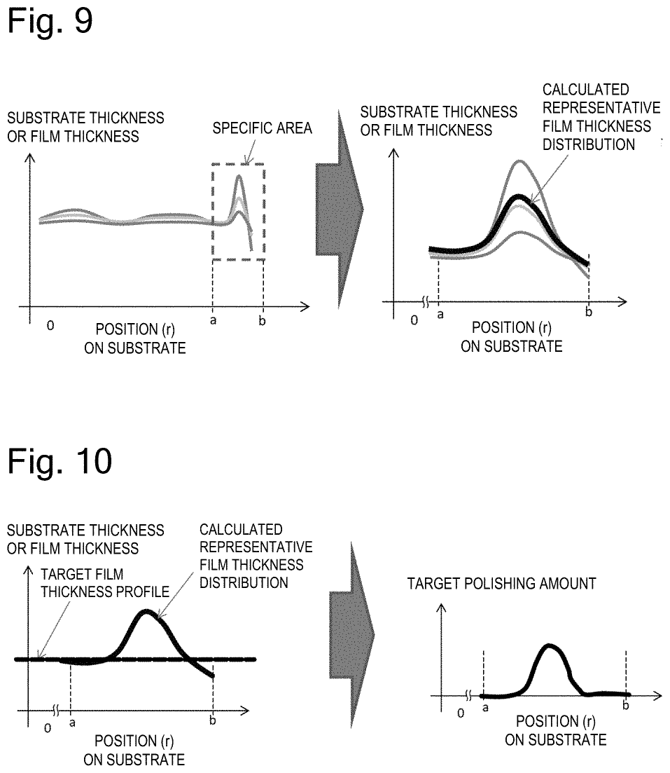

The above-described control will be illustrated with reference to FIG. 9. A graph on the left side of FIG. 9 is substantially the same as the one illustrated in FIG. 4, except that a region from a (mm) to b (mm) in the radius of the substrate Wf is indicated as a “specific area”. This “specific area” is extracted from the rt profile. A graph on the right side of FIG. 9 illustrates a portion extracted from the “specific area” of the rt profile. The control unit may calculate a representative film thickness profile after the extraction. For example, the graph on the right side of FIG. 9 illustrates three rt profiles and a representative film thickness profile (a representative film thickness distribution) obtained by averaging these three profiles. The representative film thickness profile may be calculated by another method described above.

In specifying the area to be partially polished and the partial polishing amount, the rt profile may be compared with preliminarily set target film thickness values or target film thickness profile (hereinafter, simply referred to as “target film thickness” occasionally). When it is determined that the film thickness at a certain location on the rt profile is greater than the target film thickness, the control unit specifies this location as an area to be partially polished. The target film thickness may have a certain amount of tolerance. When it is determined that the film thickness is greater beyond the tolerance range, the control unit may specify this location as an area to be partially polished. The control unit may specify the difference between the rt profile and the target film thickness as the partial polishing amount. The partial polishing amount at each radius of the area to be partially polished may be controlled by adjusting the rotational speed of the substrate Wf in such a way as to control the staying time of the polishing pad 502. Further, the control may be performed based on a cumulative polishing amount obtained by rotating the substrate Wf a plurality of times while the polishing pad 502 is in contact with the substrate Wf. In both cases, rotation conditions of the polishing pad 502 and the substrate Wf, pressing conditions of the polishing pad 502, the type of polishing liquid such as slurry, and the polishing rate for desired film thickness or unevenness state may be acquired in advance and stored as a database in the control unit, and automatic calculation may be performed when polishing conditions are set. The staying time of the polishing pad 502 and the number of rotations of the substrate Wf may be determined based on a regular polishing rate. The number of rotations of the substrate Wf may be calculated by, for example, detecting a mark such as a notch of the substrate Wf beforehand by the detection unit 408 and causing rotations with reference to the mark. The target film thickness may be calculated or determined from a polishing recipe input in advance.

The above-described control will be illustrated with reference to FIG. 10. A graph on the left side of FIG. 10 illustrates the representative film thickness profile (see the right side of FIG. 9) and the target film thickness profile (dotted line). The target film thickness profile in this example is the same value at any radial position. As another example, the target film thickness profile may have different values depending on the radial position. Next, the control unit calculates a target polishing amount (a graph on the right side of FIG. 10) by subtracting the target film thickness profile from the representative film thickness profile. When the calculation result becomes a negative value, no partial polishing is required in this location (area) and therefore the target polishing amount at this location (area) is zero or substantially zero. The control unit controls the partial polishing device 1000 according to the target polishing amount obtained in this manner.

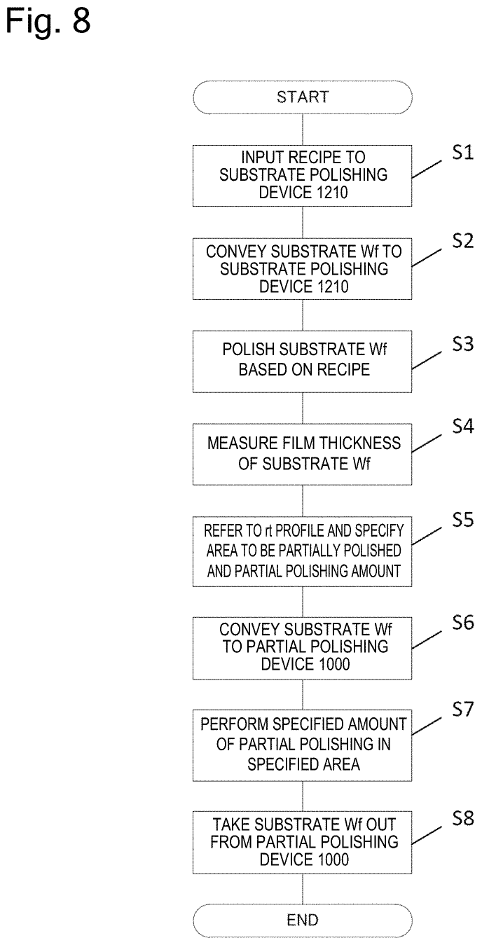

FIG. 8 is a flowchart illustrating an exemplary method for polishing a substrate by the substrate processing apparatus 100. Note that FIG. 8 is a mere example, and it is possible to delete a step, add a step, change contents, and change the order. Further, some of steps in FIG. 8 can be performed simultaneously or in parallel. For example, polishing of the substrate Wf by the substrate polishing device 1210 may not depend on the recipe, and input of recipe (step S1) may be performed after conveyance of the substrate Wf to the substrate polishing device 1210 (step S2), or simultaneously or in parallel with the conveyance. For example, a step of measuring the film thickness of the substrate Wf while supplying water (step S4) may be deleted. Alternatively, the rt profile may be acquired from the output signal of the film thickness sensor 1217 in step S3. Various other changes may be applied. Each step may be automatically controlled by the control unit or the like, or may be manually performed by an operator.

Step S 1:

A processing recipe for the substrate Wf is input to the substrate processing apparatus 100. The processing recipe may be the one input occasionally by the operator, or the one preliminarily stored in the control unit (storage unit) and read out when needed. Here, the processing recipe is prepared for each of the substrate polishing device, the partial polishing device, the cleaning device, the drying device. Further, each recipe is composed of a plurality of processing steps. Parameters in respective steps, for example, regarding the substrate polishing device, include the number of rotations of the polishing table 1211 and the polishing head 1212, pressing pressure of the substrate Wf against the polishing pad 1215, supply flow rate of the polishing liquid from the liquid-feed mechanism 1213, processing time at each step, conditions for measuring the film thickness of the substrate Wf by the film thickness sensor 1217, and the like. Further, regarding the partial polishing module, the parameters include processing time at each step, contact pressure or load of the polishing pad 502 applied to the substrate Wf or the dresser disposed on the dress table, the number of rotations of the polishing pad 502 and the substrate Wf, moving speed of the polishing head 500 in the radial direction of the substrate Wf, flow rate of the polishing liquid from the polishing liquid supply nozzle 702, the number of rotations of the dress stage 810, and the like. Further, since the conveyance route of the substrate Wf between the substrate polishing device, the partial polishing device, the cleaning device, and the drying device varies depending on each process, conveyance routes of respective constituent components may be set.

Step S2:

For example, the substrate Wf is conveyed from the load/unload unit 110 to the substrate polishing device 1210 by the conveyance robot 112 or the like. The substrate conveyed to the substrate polishing device 1210 is attached to the polishing head 1212 and pressed against the polishing pad 1215.

Step S3:

Based on the recipe input in step 51, the substrate Wf is polished by the substrate polishing device 1210. As described above, when polishing the substrate Wf, liquid such as slurry is supplied from the liquid-feed mechanism 1213, and at least one of, preferably each of, the polishing table 1211 and the polishing head 1212 is rotated. The film thickness is monitored by the film thickness sensor 1217, and the processing in step S3 terminates when the film thickness reaches a predetermined value.

Step S4:

After the polishing of the substrate Wf in step S3 is completed, the film thickness profile of the substrate Wf is measured by the film thickness sensor 1217. In this step, for example, while water (pure water) is supplied from the liquid-feed mechanism 1213, the film thickness profile of the substrate Wf is measured by the film thickness sensor 1217 and the rt profile is calculated. The sensor output map may be generated in step S4. The operation of the substrate polishing device 1210 in step S4 may include cleaning of the substrate Wf.

Step S5:

By comparing the rt profile calculated in step S4 with the target polishing profile, the area to be partially polished and the partial polishing amount are specified. The rt profile can be obtained from measurement values of the film thickness sensor 1217 or the sensor output map, as described above (see step S4). The recipe information input in step 51 may be used when specifying the area to be partially polished and the partial polishing amount.

Step S6:

The substrate Wf is removed from the polishing head 1212, and the substrate Wf is conveyed from the substrate polishing device 1210 to the partial polishing device 1000. In this case, a conveyance device such as the substrate conveyance unit 140 or the conveyance robot 131 may be used.

Step S7:

Using the partial polishing device 1000, specified amount of partial polishing is performed in the area specified in step S5. As described above, when the area to be partially polished by the partial polishing device 1000 has a ring shape, in step S7, the stage 400, the polishing head 500, the holding arm 600, and the like may be controlled based on the parameters having been set in step 51.

Step S8:

After the partial polishing is completed, the substrate Wf is taken out from the partial polishing device 1000. The substrate conveyance unit 140 or the like may be used for the taking-out operation. Subsequently, the substrate cleaning and drying unit 150 may perform cleaning of the substrate Wf and drying of the substrate Wf. Subsequently, the substrate Wf may be unloaded from the substrate processing apparatus 100 via the load/unload unit 110.

Although several embodiments of the present invention have been described, the above-described embodiments are for facilitating the understanding of the present invention and do not intend to narrowly limit the present invention. The present invention can be changed or improved without departing from the gist thereof, and equivalents thereof are encompassed in the present invention. Further, within a range where at least a part of the above-described problem can be solved or a range where at least a part of the effects is achieved, any combination or partial omission of the constituent components described in the claims and the specification will be feasible.

The present application discloses, as an embodiment, a method for specifying an area to be partially polished by a partial polishing device in a substrate processing apparatus, wherein the substrate processing apparatus includes a substrate polishing device that polishes an entire surface of a film to be processed formed on at least one surface of a substrate and includes a film thickness sensor, and a partial polishing device that further partially polishes the film to be processed of the substrate polished by the substrate polishing device. The method includes specifying an area to be partially polished by the partial polishing device based on film thickness distribution data of the film to be processed obtained from the film thickness sensor of the substrate polishing device. The substrate polishing device may press the entire surface of the film to be processed against a polishing pad disposed on a polishing table and polish the film to be processed by chemical mechanical polishing by causing the substrate and the polishing pad to relatively move while supplying slurry by a liquid-feed mechanism. The film thickness sensor may measure a film thickness distribution of the film to be processed within a plane of the substrate .

This method brings effects of quickly grasping a film thickness distribution of the film to be processed on the substrate after CMP and realizing high-speed substrate processing.

Further, the present application discloses, as an embodiment, a method in which the film thickness distribution data of the film to be processed obtained from the film thickness sensor is a two-dimensional film thickness profile including a radius from a center of the substrate as one dimension and a film thickness of the film to be processed as another dimension.

Further, the present application discloses, as an embodiment, a method in which in the specifying of the area to be partially polished, a representative film thickness profile calculated based on a plurality of film thickness profiles is used to specify the area to be partially polished with respect to a radial direction of the substrate.

Further, the present application discloses, as an embodiment, a method in which in a phase of specifying the area to be partially polished using the representative film thickness profile, the representative film thickness profile is calculated based on an average value of respective film thicknesses at respective radii for the plurality of film thickness profiles, and the area to be partially polished is specified with respect to the radial direction of the substrate using the calculated representative film thickness profile.

Further, the present application discloses, as an embodiment, a method in which the film thickness profile is a film thickness profile obtained from actual measurement values of the film thickness sensor or a film thickness profile extracted from a sensor output map generated based on signals output from the film thickness sensor.

Further, the present application discloses, as an embodiment, a method in which the area to be partially polished is specified with respect to the radial direction of the substrate by comparing the film thickness profile with a predetermined target film thickness profile.

Further, the present application discloses, as an embodiment, a method in which a polishing amount distribution in the area to be partially polished is further specified based on differences between the film thickness profile or the representative film thickness profile and the target film thickness profile.

Further, the present application discloses, as an embodiment, a method in which the data obtained from the film thickness sensor is data obtained by causing the film thickness sensor to operate while supplying water from the liquid-feed mechanism of the substrate polishing device to the polishing pad after completing the polishing of the film to be processed by the substrate polishing device. The film to be processed may be polished with slurry.

Further, the present application discloses, as an embodiment, a method in which the substrate polishing device includes a plurality of film thickness sensors on the polishing table.

Further, the present application discloses, as an embodiment, a substrate processing apparatus including a substrate polishing device that polishes an entire surface of a film to be processed formed on at least one surface of a substrate. The substrate polishing device includes a polishing table to which a polishing pad is attached, a substrate holding part that holds the substrate and pressing the film to be processed against the polishing pad, and a film thickness sensor that measures a film thickness distribution of the film to be processed within the substrate surface, and the substrate polishing device is capable of causing the substrate and the polishing pad to relatively move. The substrate processing apparatus includes a partial polishing device that further partially polishes the film to be processed of the substrate polished by the substrate polishing device, and a control unit. The control unit specifies an area to be partially polished by the partial polishing device based on film thickness distribution data of the film to be processed obtained from the film thickness sensor of the substrate polishing device. The substrate processing apparatus may include a liquid-feed mechanism that supplies any one of slurry, pure water, and chemical liquid onto the polishing pad.

Further, the present application discloses, as an embodiment, a substrate processing apparatus in which the film thickness distribution data of the film to be processed obtained from the film thickness sensor is a two-dimensional film thickness profile including a radius from a center of the substrate as one dimension and a film thickness as another dimension.

Further, the present application discloses, as an embodiment, a substrate processing apparatus further including a cleaning device that cleans the substrate polished by the substrate polishing device or the partial polishing device, a drying device that dries the substrate after the cleaning of the substrate, and a conveyance device that conveys the substrate between the substrate polishing device, the partial polishing device, the cleaning device, and the drying device, wherein the control unit controls operations of the substrate polishing device, the partial polishing device, the cleaning device, the drying device, and the conveyance device.

### REFERENCE SIGNS LIST

100: substrate processing apparatus

110: load/unload unit

111: FOUP

112: conveyance robot

120: polishing unit

121: first polishing device

122: second polishing device

123: third polishing device

124: fourth polishing device

130: substrate conveyance unit

131: conveyance robot

132: station

140: substrate conveyance unit (linear transporter)

150: substrate cleaning and drying unit

151: first cleaning module

152: second cleaning module

153: drying module

154: first cleaning unit conveyance robot

155: second cleaning unit conveyance robot

160: control unit

190: sensor output map

200: cleaning mechanism

202: cleaning head

204: cleaning member

206: cleaning head holding arm

208: rinse nozzle

400: stage

400A: rotation axis

402: lift pin

404: positioning mechanism

406: positioning pad

408: detection unit

410: rotation driving mechanism

500: polishing head

502: polishing pad

510: rotating shaft

600: holding arm

602: vertical driving mechanism

620: horizontal driving mechanism

702: polishing liquid supply nozzle

800: conditioning unit

810: dress stage

820: dresser

850: second conditioner

852: conditioning member

900: control unit

1000: partial polishing device

1002: base surface

1210: substrate polishing device

1211: polishing table

1212: polishing head

1213: liquid-feed mechanism

1214: control unit

1215: polishing pad

1216: airbag

1217: film thickness sensor

Wf: substrate

I/O: input/output device

PRO: processor

STO: storage device

What is claimed is:

1. A method for specifying an area to be partially polished by a partial polishing device in a substrate processing apparatus, wherein
the substrate processing apparatus includes:
a substrate polishing device that polishes an entire surface of a film to be processed formed on at least one surface of a substrate and includes a film thickness sensor; and
the partial polishing device that further partially polishes the film to be processed of the substrate polished by the substrate polishing device, and
the method comprises specifying an area to be partially polished by the partial polishing device based on film thickness distribution data of the film to be processed obtained from the film thickness sensor of the substrate polishing device.

2. The method according to claim 1, wherein
the substrate polishing device presses the entire surface of the film to be processed against a polishing pad disposed on a polishing table and polishes the film to be processed by chemical mechanical polishing by causing the substrate and the polishing pad to relatively move while supplying slurry by a liquid-feed mechanism.

3. The method according to claim 1, wherein
the film thickness sensor measures a film thickness distribution of the film to be processed within a plane of the substrate.

4. The method according to claim 1, wherein
the film thickness distribution data of the film to be processed obtained from the film thickness sensor is a two-dimensional film thickness profile including a radius from a center of the substrate as one dimension and a film thickness of the film to be processed as another dimension.

5. The method according to claim 4, wherein
in the specifying of the area to be partially polished, a representative film thickness profile calculated based on a plurality of film thickness profiles is used to specify the area to be partially polished with respect to a radial direction of the substrate.

6. The method according to claim 5, wherein
in a phase of specifying the area to be partially polished using the representative film thickness profile, the representative film thickness profile is calculated based on an average value of respective film thicknesses at respective radii for the plurality of film thickness profiles, and the area to be partially polished is specified with respect to the radial direction of the substrate using the calculated representative film thickness profile.

7. The method according to claim 4, wherein
the film thickness profile is a film thickness profile obtained from actual measurement values of the film thickness sensor or a film thickness profile extracted from a sensor output map generated based on signals output from the film thickness sensor.

8. The method according to claim 4, wherein
the area to be partially polished is specified with respect to the radial direction of the substrate by comparing the film thickness profile with a predetermined target film thickness profile.

9. The method according to claim 8, wherein
a polishing amount distribution in the area to be partially polished is further specified based on differences between the film thickness profile or the representative film thickness profile and the target film thickness profile.

10. The method according to claim 1, wherein
the data obtained from the film thickness sensor is data obtained by causing the film thickness sensor to operate while supplying water from the liquid-feed mechanism of the substrate polishing device to the polishing pad after completing the polishing of the film to be processed by the substrate polishing device.

11. The method according to claim 10, wherein
the film to be processed is polished with slurry.

12. The method according to claim 1, wherein
the substrate polishing device includes a plurality of film thickness sensors on the polishing table.

13. A substrate processing apparatus comprising:
a substrate polishing device that polishes an entire surface of a film to be processed formed on at least one surface of a substrate, the substrate polishing device including a polishing table to which a polishing pad is attached, a substrate holding part that holds the substrate and pressing the film to be processed against the polishing pad, and a film thickness sensor that measures a film thickness distribution of the film to be processed within the substrate surface, the substrate polishing device being capable of causing the substrate and the polishing pad to relatively move;
a partial polishing device that further partially polishes the film to be processed of the substrate polished by the substrate polishing device; and
a control unit,
wherein the control unit specifies an area to be partially polished by the partial polishing device based on film thickness distribution data of the film to be processed obtained from the film thickness sensor of the substrate polishing device.

14. The substrate processing apparatus according to claim 13, wherein
the film thickness distribution data of the film to be processed obtained from the film thickness sensor is a two-dimensional film thickness profile including a radius from a center of the substrate as one dimension and a film thickness as another dimension.

15. The substrate processing apparatus according to claim 13, further comprising
a liquid-feed mechanism that supplies any one of slurry, pure water, and chemical liquid onto the polishing pad.

16. The substrate processing apparatus according to claim 13, further comprising:
a cleaning device that cleans the substrate polished by the substrate polishing device or the partial polishing device;
a drying device that dries the substrate after the cleaning of the substrate; and
a conveyance device that conveys the substrate between the substrate polishing device, the partial polishing device, the cleaning device, and the drying device,
wherein the control unit controls operations of the substrate polishing device, the partial polishing device, the cleaning device, the drying device, and the conveyance device.
